(19) United States
(12) Patent Application Publication
(10) Pub. No.: US 2024/0215339 A1
(43) Pub. Date: Jun. 27, 2024

(54) DISPLAY DEVICE AND METHOD OF MANUFACTURING THE SAME

(71) Applicant: Samsung Display Co., LTD., Yongin-si (KR)

(72) Inventors: KOICHI SUGITANI, Yongin-si (KR); GWUI-HYUN PARK, Yongin-si (KR); HOKYUNG JANG, Yongin-si (KR); SAEHEE HAN, Yongin-si (KR)

(73) Assignee: Samsung Display Co., LTD., Yongin-si (KR)

(21) Appl. No.: 18/455,666

(22) Filed: Aug. 25, 2023

(30) Foreign Application Priority Data
Dec. 22, 2022 (KR) 10-2022-0181684

(51) Int. Cl. H10K 59/124; H10K 59/12; H10K 59/123; H10K 59/131

(52) U.S. Cl. CPC H10K 59/124; H10K 59/1201; H10K 59/123; H10K 59/131; H10K 71/621

(57) ABSTRACT

A display device includes a light emitting area and a non-light emitting area adjacent to the light emitting area, a first conductive layer disposed on a substrate in the light emitting area and the non-light emitting area, a second conductive layer disposed on the first conductive layer in the light emitting area, a first insulating film disposed on the first conductive layer, overlapping the first conductive layer and the second conductive layer in the light emitting area, and having a first permittivity, and a second insulating film disposed between the first insulating film and the second conductive layer, disposed in the light emitting area and the non-light emitting area, overlapping the first insulating film and the first conductive layer, and having a second permittivity greater than the first permittivity.

### CROSS-REFERENCE TO RELATED APPLICATION(S)

This application claims priority to and benefits of Korean Patent Application No. 10-2022-0181684 under 35 USC § 119, filed on Dec. 22, 2022 in the Korean Intellectual Property Office (KIPO), the entire disclosure of which is incorporated by reference herein.

### BACKGROUND

### 1. Technical Field

Embodiments relate to a display device. More specifically, embodiments relate to a display device that displays an image and a method of manufacturing the display device.

### 2. Description of the Related Art

A display device is a device that displays an image to provide visual information to a user. Among display devices, an organic light-emitting diode display (OLED display) has recently been attracting attention.

The display device may include a display panel and a panel driver (e.g., a data driver, a gate driver, and the like). Conductive patterns may be sequentially formed on the display panel, and the conductive patterns may contact each other through contacts. The panel driver may provide signals and/or voltages to the conductive patterns of the display panel. The conductive patterns may be patterned to have unit structures that are repetitive in a plan view, and the conductive patterns having one of the unit structures may be defined as a pixel structure.

On the other hand, to reduce dead space in the display panel, lines connecting the display panel and the panel driver may be disposed in a display area. The lines may be formed of the conductive patterns, and parasitic capacitance may be generated due to overlapping of the conductive patterns. In this case, stains may occur in the display panel of the display device due to the parasitic capacitance, and display quality may deteriorate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure may provide a display device with improved display quality.

The disclosure may provide a method of manufacturing the display device.

The technical objectives to be achieved by the disclosure are not limited to those described herein, and other technical objectives that are not mentioned herein would be clearly understood by a person skilled in the art from the description of the disclosure.

A display device according to embodiments of the disclosure includes a light emitting area and a non-light emitting area adjacent to the light emitting area, a first conductive layer disposed on a substrate in the light emitting area and the non-light emitting area, a second conductive layer disposed on the first conductive layer and disposed in the light emitting area, a first insulating film disposed on the first conductive layer, overlapping the first conductive layer and the second conductive layer in the light emitting area, and having a first permittivity, and a second insulating film disposed between the first insulating film and the second conductive layer, disposed in the light emitting area and the non-light emitting area, overlapping the first insulating film and the first conductive layer, and having a second permittivity greater than the first permittivity.

In an embodiment, the first insulating film and the second insulating film may include different materials.

In an embodiment, the first insulating film may include at least one selected from a group consisting of acrylate and siloxane hybrid.

In an embodiment, the second insulating film may include a photo-sensitive polyimide-based resin.

In an embodiment, the first insulating film may have a same shape as the first conductive layer in the light emitting area.

In an embodiment, the first conductive layer may define at least one first opening disposed in the light emitting area, and the first insulating film may define at least one second opening disposed in the light emitting area.

In an embodiment, the first opening and the second opening may overlap each other.

In an embodiment, the display device may further include a light emitting diode disposed on the first conductive layer and disposed in the light emitting area.

In an embodiment, the light emitting diode may include the second conductive layer, a light emitting layer disposed on the second conductive layer, and a common electrode disposed on the light emitting layer.

In an embodiment, the display device may further include a transistor disposed on the substrate and disposed under the first conductive layer.

In an embodiment, the transistor may further include an active layer disposed on the substrate, a gate electrode disposed on the active layer, and a source electrode and a drain electrode connected to the active layer on the gate electrode.

In an embodiment, the transistor may be electrically connected to the light emitting diode through the first conductive layer.

In an embodiment, the first conductive layer may further include a data line.

In an embodiment, each of the first conductive layer and the second conductive layer may include a metal material.

In an embodiment, the second conductive layer may include at least one selected from a group consisting of indium tin oxide (ITO), indium zinc oxide (IZO), zinc oxide (ZnO), indium oxide (In₂O₃), indium gallium oxide (IGO), and aluminum zinc oxide (AZO).

A method of manufacturing a display device includes forming a first conductive layer on a substrate, forming a first insulating film on the first conductive layer, overlapping the first conductive layer in a light emitting area of the display device, and having a first permittivity, forming a second insulating film on the first insulating film, overlapping the first insulating film and the first conductive layer, and having a second permittivity greater than the first permittivity, and forming a second conductive layer on the second insulating film and overlapping the first insulating film in the light emitting area.

In an embodiment, the forming of the first conductive layer and the first insulating film may include forming a first preliminary conductive layer on the substrate, forming a photoresist layer on the first preliminary conductive layer, forming a photoresist pattern including a first portion and a second portion having different thicknesses by patterning the photoresist layer, forming a first conductive layer by patterning the first preliminary conductive layer with the photoresist pattern, and forming the first insulating film by ashing the photoresist pattern.

In an embodiment, a thickness of the first portion may be smaller than a thickness of the second portion.

In an embodiment, the photoresist pattern may be patterned by using a half-tone mask.

In an embodiment, in the ashing of the photoresist pattern, the first portion and the second portion may be removed by a uniform thickness.

In an embodiment, the first insulating film may be formed by removing the first portion and the second portion of the photoresist pattern by the uniform thickness to remove an entirety of the first portion entirely and a portion of the second portion.

In an embodiment, the first portion may overlap the first conductive layer in a non-light emitting area of the display device, and the second portion overlaps the first conductive layer in the light emitting area.

In an embodiment, the photoresist layer may include at least one selected from a group consisting of acrylate and siloxane hybrid.

In a display device according to embodiments of the disclosure, the display device further includes a first insulating film having a smaller permittivity than a second insulating film, so that the permittivity of a via insulating layer between a first conductive layer and a second conductive layer may be reduced. Accordingly, parasitic capacitance between the first conductive layer and the second conductive layer may be reduced. By reducing the parasitic capacitance, a stain of a display area of the display device may be prevented. Accordingly, a display quality of the display device may be improved.

In addition, since the first insulating film is disposed to overlap only the first conductive layer and the second conductive layer, defects due to outgas generated by the first insulating film may be minimized. Accordingly, a reliability of the display device may be improved.

By forming the first insulating film using a half-tone mask and an ashing process, an additional process for forming the first insulating film may be omitted. Therefore, while reducing the permittivity of the second via insulating layer with the first insulating layer, and efficiency of manufacturing process might not decrease.

### BRIEF DESCRIPTION OF THE DRAWINGS

FIG. 1 is a schematic plan view illustrating a display device according to an embodiment of the disclosure.

FIG. 2 is a schematic enlarged plan view of area A of FIG. 1.

FIG. 3 is a schematic enlarged plan view of a partial area of FIG. 1.

FIG. 4 is a schematic plan view illustrating only the first conductive layer in FIG. 3.

FIG. 5 is a schematic plan view illustrating the first conductive layer and the first insulating film in FIG. 3.

FIG. 6 is a schematic cross-sectional view taken away from a portion of FIG. 3.

FIG. 7 is a graph illustrating the permittivity of the second via insulating layer depending on the thickness of the first insulating film.

FIGS. 8 to 21 are schematic views illustrating a method of manufacturing a display device according to an embodiment of the disclosure.

### DETAILED DESCRIPTION OF THE EMBODIMENTS

Hereinafter, embodiments of the disclosure will be described in more detail with reference to the accompanying drawings. The same reference numerals are used for the same components in the drawings, and redundant descriptions of the same components will be omitted.

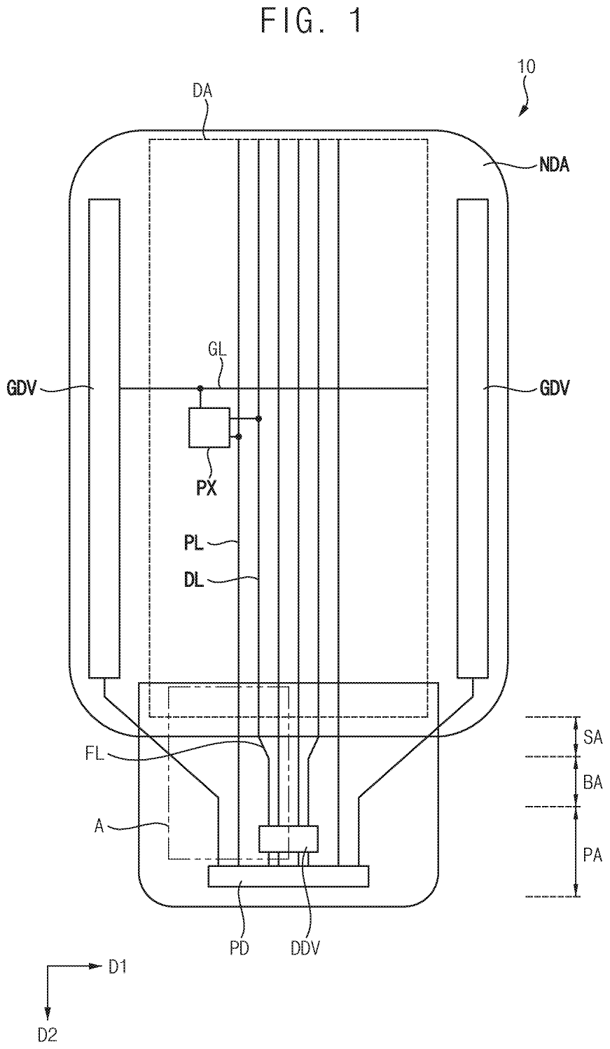

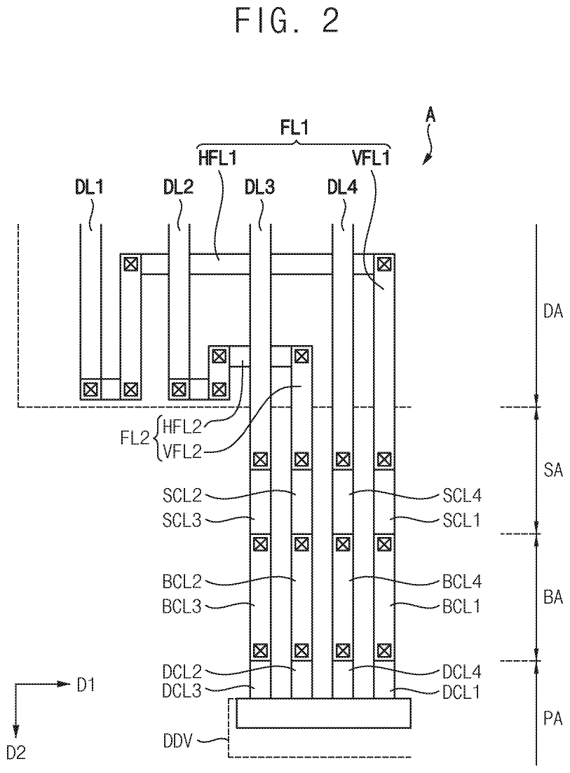

FIG. 1 is a schematic plan view illustrating a display device 10 according to an embodiment of the disclosure. FIG. 2 is a schematic enlarged plan view of area A of FIG. 1.

Referring to FIGS. 1 and 2, the display device 10 May include a display area DA, a non-display area NDA adjacent to or surrounding the display area DA, a bending area BA capable of bending, a peripheral area SA between the display area DA and the bending area BA, and a pad area PA.

For example, a pixel structure PX may be disposed in the display area DA, and a driver for driving the pixel structure PX may be disposed in the non-display area NDA. For example, a pad part PD and a data driving part DDV may be disposed in the pad area PA, and the bending area BA may be bent around a virtual bending axis.

In the display area DA, the pixel structure PX and lines connected to the pixel structure PX, e.g., a data line DL, a gate line GL, a high power supply voltage line PL, and data transfer lines FL (e.g., FL1 and FL2), may be disposed.

The data line DL may be electrically connected to the data driving part DDV and may extend in a second direction D2. The gate line GL may be connected to a gate driving part GDV and may extend in a first direction D1 crossing (or intersecting) the second direction D2. The high power supply voltage line PL may be connected to the pad part PD and may extend in the second direction D2.

The data transfer lines FL1 and FL2 may be electrically connected to the data driving part DDV and the data line DL. The data transfer lines FL1 and FL2 may be connected the data driving part DDV and the data line DL.

In an embodiment, as shown in FIG. 2, a first data line DL1, a second data line DL2, a third data line DL3, a fourth data line DL4, a first data transfer line FL1, and a second data transfer line FL2 may be disposed in the display device 10. For example, the first data transfer line FL1, and the second data transfer line FL2 may be fan-out lines electrically connecting the data driving part DDV and the data line DL. However, since this is an embodiment for ease of illustration, the disclosure is not limited there.

In an embodiment, the first data transfer line FL1 may include at least one of a first vertical transfer line VFL1 and a first data transfer horizontal line HFL1, and the second data transfer line FL2 may include at least one of a second vertical transfer line VFL2 and a second data transfer horizontal line HFL2. For example, both the first vertical transfer line VFL1 and the second vertical transfer line VFL2 may extend in the second direction D2, and both the first data transfer horizontal line HFL1 and the second data transfer horizontal line HFL2 may extend in the first direction D1.

The first data transfer line FL1 may electrically connect the data driving part DDV and the first data line DL1. For example, a first data voltage may be provided to a first pixel structure through the first data transfer line FL1 and the first data line DL1.

Specifically, the first vertical transfer line VFL1 may be connected to a first connection line SCL1, the first connection line SCL1 may be connected to a first bending connection line BCL1, and the first bending connection line BCL1 may be connected to a first data connection line DCL1.

For example, the first vertical transfer line VFL1 may extend from the peripheral area SA to the display area DA and may be formed on a first layer. The first connection line SCL1 may be formed on a second layer disposed under the first layer in the peripheral area SA. The first bending connection line BCL1 may be disposed in the bending area BA and may be formed on the first layer. The first data connection line DCL1 may be disposed in the pad area PA and may receive the first data voltage from the data driving part DDV.

The second data transfer line FL2 may electrically connect the data driving part DDV and the second data line DL2. For example, a second data voltage may be provided to a second pixel structure through the second data transfer line FL2 and the second data line DL2.

Specifically, the second vertical transfer line VFL2 may be connected to a second connection line SCL2, the second connection line SCL2 may be connected to a second bending connection line BCL2, and the second bending connection line BCL2 may be connected to a second data connection line DCL2. In an embodiment, a structure of the second vertical transfer line VFL2, the second connection line SCL2, the second bending connection line BCL2, and the second data connection line DCL2 may have a substantially same structure as the first vertical transfer line VFL1, the first connection line SCL1, the first bending connection line BCL1, and the first data connection line DCL1, respectively, so detailed descriptions thereof will be omitted. However, the disclosure is not limited thereto. In other words, the structure of the first vertical transfer line VFL1, the first connection line SCL1, the first bending connection line BCL1, and the first data connection line DCL1 and the structure of the second vertical transfer line VFL2, the second connection line SCL2, the second bending connection line BCL2, and the second data connection line DCL2 may be different from each other.

The third data line DL3 may be connected to the data driving part DDV. For example, a third data voltage may be provided to a third pixel structure through the third data line DL3.

Specifically, the third data line DL3 may be connected to a third connection line SCL3, the third connection line SCL3 may be connected to a third bending connection line BCL3, and the third bending connection line BCL3 may be connected to a third data connection line DCL3.

For example, the third data line DL3 may extend from the peripheral area SA to the display area DA and may be formed on the first layer. The third connection line SCL3 may be formed on a third layer disposed under the first layer in the peripheral area SA. The third bending connection line BCL3 may be disposed in the bending area BA and may be formed on the first layer. The third data connection line DCL3 may be disposed in the pad area PA and receive the third data voltage from the data driving part DDV.

The fourth data line DL4 may be connected to the data driving part DDV. For example, a fourth data voltage may be provided to a fourth pixel structure through the fourth data line DL4.

Specifically, the fourth data line DL4 may be connected to a fourth connection line SCL4, the fourth connection line SCL4 may be connected to a fourth bending connection line BCL4, and the fourth bending connection line BCL4 may be connected to a fourth data connection line DCL4. However, a structure of the fourth data line DL4, the fourth connection line SCL4, the fourth bending connection line BCL4, and the fourth data connection line DCL4 may have a substantially same structure as the third data line DL3, the third connection line SCL3, the third bending connection line BCL3, and the third data connection line DCL3, respectively, so detailed descriptions thereof will be omitted. However, the disclosure is not limited thereto. In other words, the structure of the fourth data line DL4, the fourth connection line SCL4, the fourth bending connection line BCL4, and the fourth data connection line DCL4 and the structure of the third data line DL3, the third connection line SCL3, the third bending connection line BCL3, and the third data connection line DCL3 may be different from each other.

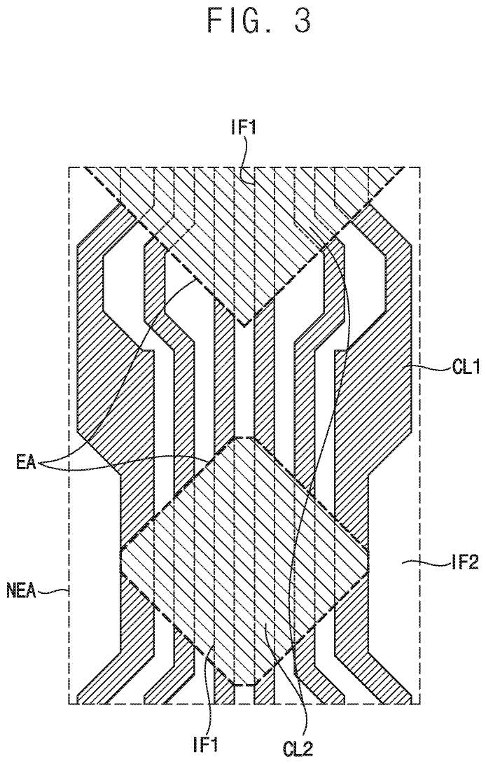

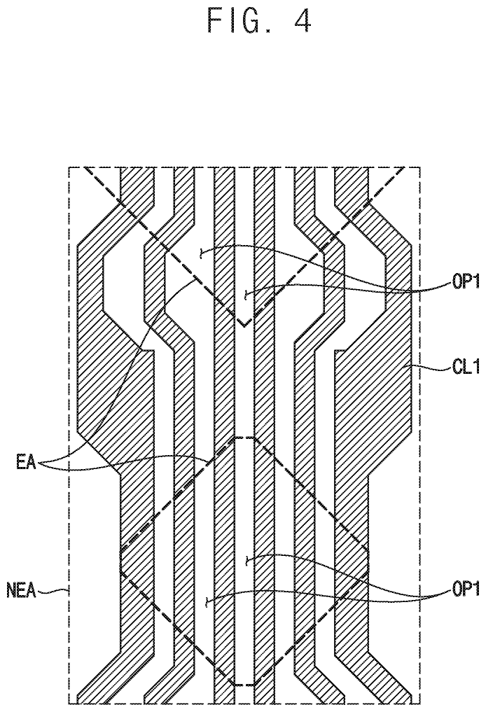

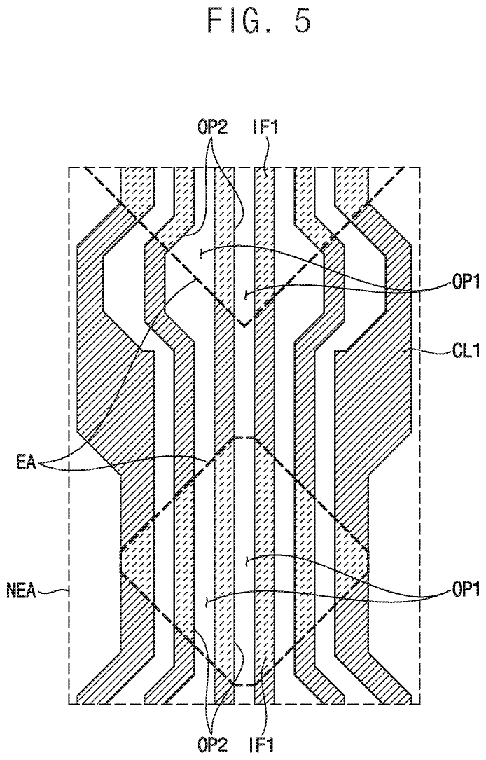

FIG. 3 is a schematic enlarged plan view of a partial area of FIG. 1. FIG. 4 is a schematic plan view illustrating only the first conductive layer in FIG. 3. FIG. 5 is a schematic plan view illustrating the first conductive layer and the first insulating film in FIG. 3.

For example, FIG. 3 May be an enlarged plan view of a partial area of the display area of FIG. 2.

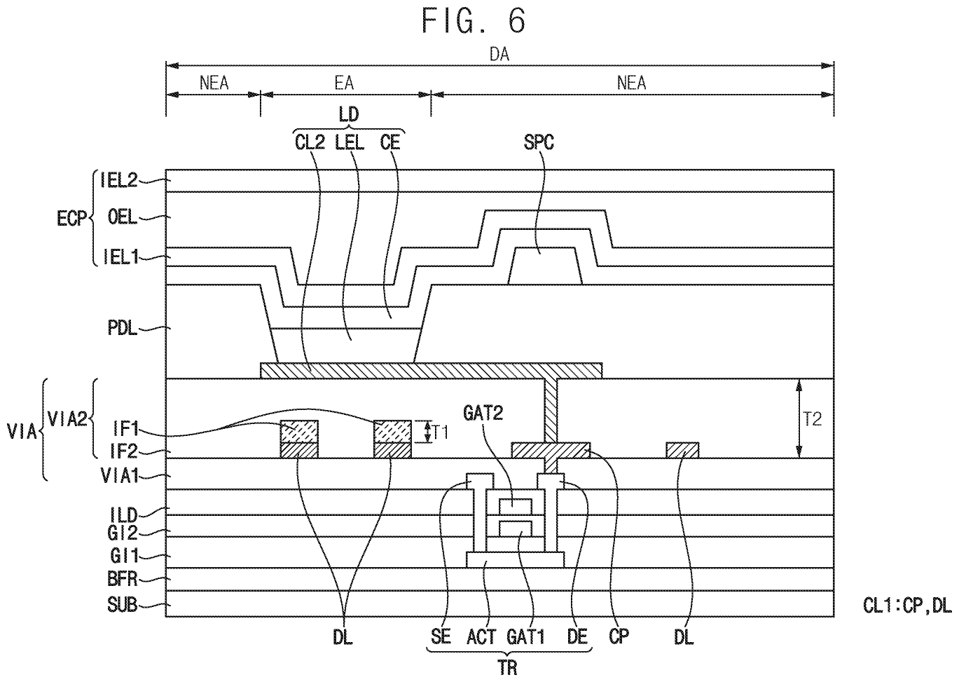

Referring to FIGS. 1, 2, and 3, the display device 10 May include a substrate (e.g., a substrate SUB of FIG. 6). As the display device 10 includes the display area DA and the non-display area NDA, the substrate may include the display area DA and the non-display area NDA. The display area DA may include a light emitting area EA and a non-light emitting area NEA. The light emitting area EA may be an area in which light generated in the display device 10 is emitted. The non-light emitting area NEA may be adjacent to the light emitting area EA. The non-light emitting area NEA may surround the light emitting area EA and may be an area where the light generated in the display device 10 is not emitted.

Referring to FIGS. 4 and 5, the display device 10 May further include at least one of a first conductive layer CL1, a second conductive layer CL2, a first insulating film IF1, and a second insulating film IF2.

The first conductive layer CL1 may be disposed on the substrate. The first conductive layer CL1 may be disposed in the light emitting area EA and the non-light emitting area NEA. The first conductive layer CL1 may include one or more lines. For example, the first conductive layer CL1 may include the data line DL, the vertical transfer lines VFL1 and VFL2, and a power line. The lines may be spaced apart from each other. However, the disclosure is not limited thereto.

The first conductive layer CL1 may include a metal material. For example, examples of the metal material constituting the first conductive layer CL1 may include at least one of aluminum, titanium, and the like. The above metal materials may be used alone or in combination. However, the disclosure is not limited thereto.

The second conductive layer CL2 may be disposed on the first conductive layer CL1. The second conductive layer CL2 may overlap or be disposed in the light emitting area EA. For example, the light emitting area EA may be defined as an area in which the second conductive layer CL2 is disposed. The second conductive layer CL2 may include a metal material. For example, the second conductive layer CL2 may include at least one of indium tin oxide (ITO), indium zinc oxide (IZO), zinc oxide (ZnO), indium oxide (In₂O₃). indium gallium oxide (IGO), aluminum zinc oxide (AZO), and the like. The above metal materials may be used alone or in combination. However, the disclosure is not limited thereto.

The first insulating film IF1 may be disposed on the first conductive layer CL1 and may be disposed under the second conductive layer CL2. The first insulating film IF1 may overlap the light emitting area EA. In addition, the first insulating film IF1 may be spaced apart from the non- light emitting area NEA.

In an embodiment, the first insulating film IF1 may overlap both the first conductive layer CL1 and the second conductive layer CL2 in the light emitting area EA. Specifically, the second conductive layer CL2 may have a substantially same shape as the light emitting area EA, and the first insulating film IF1 may have a substantially a same shape as the first conductive layer CL1 in the light emitting area EA. The first insulating film IF1 may partially expose a first via insulating layer (e.g., a first via insulating layer VIA1 of FIG. 5) under the first conductive layer CL1. An exposed portion of the first via insulating layer may be a portion that does not overlap the first conductive layer CL1 in the light emitting area EA.

In other words, the first conductive layer CL1 may define at least one first opening OP1 in the light emitting area EA (or overlapping the light emitting area EA in the light emitting area EA). The first opening OP1 may be defined between the lines spaced apart from each other. In addition, the first insulating film IF1 may define at least one second opening OP2 in the light emitting area EA (or overlapping the light emitting area EA in the light emitting area EA). The second opening OP2 may overlap the first opening OP1.

The second insulating film IF2 may be disposed between the first insulating film IF1 and the second conductive layer CL2. The second insulating film IF2 may be disposed in the light emitting area EA and the non-light emitting area NEA. For example, the second insulating film IF2 may cover (or overlap) the first insulating film IF1 and the first conductive layer CL1 as a whole.

In an embodiment, the first insulating film IF1 and the second insulating film IF2 may include different materials. The first insulating film IF1 may include at least one of acrylate, siloxane hybrid, and the like. These materials may be used alone or in combination. The second insulating film IF2 may include a photo-sensitive polyimide based resin. However, the disclosure is not limited thereto.

In an embodiment, the first insulating film IF1 may have a first permittivity. The second insulating film IF2 may have a second permittivity. The second permittivity may be greater than the first permittivity. For example, the first and second insulating films IF1 and IF2 having different permittivity may be disposed between the first conductive layer CL1 and the second conductive layer CL2.

FIG. 6 is a schematic cross-sectional view taken away from a portion of FIG. 3.

Referring to FIGS. 3, 4, 5, and 6, the display device 10 May further include a buffer layer BFR, insulating layers, a transistor TR, the data line DL, a connection pattern CP, a light emitting diode LD, and an encapsulation layer ECP.

The buffer layer BFR may be disposed on the substrate SUB. The buffer layer BFR may prevent diffusion of metal atoms or impurities from the substrate SUB into an active layer ACT.

The transistor TR may be disposed in the display area DA on the substrate SUB. The transistor TR may include the active layer ACT, a gate electrode GAT1, a source electrode SE, and a drain electrode DE.

Specifically, the active layer ACT may be disposed on the buffer layer BFR. The active layer ACT may be divided into a source area and a drain area doped with impurities and a channel area between the source area and the drain area.

A first gate insulating layer GI1 may be disposed on the buffer layer BFR. The first gate insulating layer GI1 may cover the active layer ACT in the display area DA, and may be formed to have substantially a same thickness along a profile of the active layer ACT. However, embodiments according to the disclosure are not limited thereto. In an embodiment, the first gate insulating layer GI1 may include an inorganic material.

The gate electrode GAT1 may be disposed on the first gate insulating layer GI1. The gate electrode GAT1 may overlap the channel area of the active layer ACT.

A second gate insulating layer GI2 may be disposed on the first gate insulating layer GI1. In addition, the second gate insulating layer GI2 may cover the gate electrode GAT1 and may be disposed to have a substantially same thickness along a profile of the gate electrode GAT1. However, embodiments according to the disclosure are not limited thereto. In an embodiment, the second gate insulating layer GI2 may include an inorganic material. The second gate insulating layer GI2 may be disposed from the display area DA to the non-display area NDA.

A capacitor electrode GAT2 may be disposed on the second gate insulating layer GI2 in the display area DA. The capacitor electrode GAT2 may be a capacitor electrode. The capacitor electrode GAT2 and the gate electrode GAT1 may constitute a capacitor.

An interlayer insulating layer ILD may be disposed on the second gate insulating layer GI2. In addition, the interlayer insulating layer ILD may cover the capacitor electrode GAT2 and may have a substantially same thickness along a profile of the capacitor electrode GAT2. However, embodiments according to the disclosure are not limited thereto. In an embodiment, the interlayer insulating layer ILD may include an inorganic material. The interlayer insulating layer ILD may be disposed from the display area DA to the non-display area NDA as a whole.

The source electrode SE and the drain electrode DE may be disposed on the interlayer insulating layer ILD. The source electrode SE and the drain electrode DE may be connected to the active layer ACT. The source electrode SE may be in contact with the source area of the active layer ACT through a first contact hole formed in the first gate insulating layer GI1, the second gate insulating layer GI2, and the interlayer insulating layer ILD. The drain electrode DE may be in contact with the drain area of the active layer ACT through a second contact hole formed in in the first gate insulating layer GI1, the second gate insulating layer GI2, and the interlayer insulating layer ILD.

The first via insulating layer VIA1 may be disposed on the interlayer insulating layer ILD. In addition, the first via insulating layer VIA1 may cover the source electrode SE and the drain electrode DE, might not create a step around the source electrode SE and the drain electrode DE, and may have a substantially flat upper surface. However, embodiments according to the disclosure are not limited thereto. In an embodiment, the first via insulating layer VIA1 may include an organic material.

In the display area DA, the first conductive layer CL1 may be disposed on the first via insulating layer VIA1. The first conductive layer CL1 may include the connection pattern CP and the data lines DL. The connection pattern CP may contact the drain electrode DE or the source electrode SE through a third contact hole formed in the first via insulating layer VIA1. The transistor TR and the light emitting diode LD may be connected through the connection pattern CP.

The data lines DL may include a data line overlapping the light emitting area EA and a data line overlapping the non-light emitting area NEA. The data lines DL may be spaced apart from the connection pattern CP. The data lines DL may be connected to the transistor TR. The data lines DL may transfer a data signal to the transistor TR.

A second via insulating layer VIA2 may be disposed on the first via insulating layer VIA1. The second via insulating layer VIA2 may cover the first conductive layer CL1 and may have a substantially flat upper surface without creating a step around the first conductive layer CL1. However, embodiments according to the disclosure are not limited thereto. In an embodiment, the second via insulating layer VIA2 may include an organic material.

In an embodiment, the second via insulating layer VIA2 may include the first insulating film IF1 and the second insulating film IF2. The first insulating film IF1 may overlap the first conductive layer CL1 in the light emitting area EA. The first insulating film IF1 might not overlap the first conductive layer CL1 in the non-light emitting area NEA. Therefore, the first insulating film IF1 may overlap only the data line DL that is disposed in the light emitting area EA. The first insulating film IF1 might not overlap both the connection pattern CP and the data line DL in the non-light emitting area NEA. However, the disclosure is not limited thereto.

A thickness T1 of the first insulating film IF1 may be between about 1.6 micrometers and about 2.6 micrometers. In case that the thickness T1 of the first insulating film IF1 is smaller than about 1.6 micrometers, a capacitance between the first conductive layer CL1 and the second conductive layer CL2 may increase, so that stains may occur in the display device 10. In case that the thickness T1 of the first insulating film IF1 is greater than about 2.6 micrometers, outgassing due to the first insulating film IF1 may increase, so that defects due to the outgassing may occur in the display device 10.

The second insulating film IF2 may be disposed on the first via insulating layer VIA1. The second insulating film IF2 may cover the first conductive layer CL1 and the first insulating film IF1.

The first via insulating layer VIA1 and the second via insulating layer VIA2 may constitute a via insulating layer VIA. However, the disclosure is not limited thereto, and the via insulating layer VIA may further include two or more additional via insulating layers.

The light emitting diode LD may be disposed on the second insulating film IF2 included in the second via insulating layer VIA2. The light emitting diode LD may overlap or disposed in the light emitting area EA. The light emitting diode LD may include the second conductive layer CL2, a light emitting layer LEL, and a common electrode CE. The second conductive layer CL2 may have reflective or light-transmitting properties. For example, the second conductive layer CL2 may include metal.

The second conductive layer CL2 may contact the connection pattern CP through a fourth contact hole formed in the second via insulating layer VIA2. Through this, the second conductive layer CL2 may be connected to the transistor TR.

In the display area DA, a pixel defining layer PDL may be disposed on the second via insulating layer VIA2. An opening exposing an upper surface of the second conductive layer CL2 may be defined in the pixel defining layer PDL. For example, the pixel defining layer PDL may include an organic material.

A spacer may be disposed on the pixel defining layer PDL in the display area DA. For example, the spacer may include an organic material. The spacer may maintain a gap between the encapsulation layer ECP and the substrate SUB.

The light emitting layer LEL may be disposed on the second conductive layer CL2. The light emitting layer LEL may be disposed in the opening formed in the pixel defining layer PDL. In an embodiment, the light emitting layer LEL may have a multi-layer structure including a hole injection layer, a hole transport layer, an organic light emitting layer, an electron transport layer, and an electron injection layer. The organic light emitting layer may include a light emitting material.

The common electrode CE may cover the light emitting layer LEL and may be disposed on the pixel defining layer PDL. In an embodiment, the common electrode CE may have a plate shape. In addition, the common electrode CE may have reflective or light-transmitting properties. For example, the common electrode CE may include metal. The common electrode CE may extend from the display area DA to the non-display area NDA.

The encapsulation layer ECP may prevent penetration of moisture and oxygen into the light emitting diode LD from outside. For example, the encapsulation layer ECP may include at least one of a first inorganic encapsulation layer IEL1, an organic encapsulation layer OEL, and a second inorganic encapsulation layer IEL2.

The first inorganic encapsulation layer IEL1 may be disposed on the common electrode CE and may have substantially a same thickness along a profile of the common electrode CE. The organic encapsulation layer OEL may be disposed on the first inorganic encapsulation layer IEL1, and may have a substantially flat upper surface without creating a step around the first inorganic encapsulation layer IEL1. The second inorganic encapsulation layer IEL2 may be disposed on the organic encapsulation layer OEL.

In an embodiment, as the second via insulating layer VIA2 included in the display device 10 includes the first insulating film IF1 having the permittivity smaller than that of the second insulating film IF2, the permittivity of the second via insulating layer VIA2 between the first conductive layer CL1 and the second conductive layer CL2 may decrease. Accordingly, parasitic capacitance between the first conductive layer CL1 and the second conductive layer CL2 may be reduced. As the parasitic capacitance is reduced, stains of the display area DA of the display device 10 May be prevented. Accordingly, display quality of the display device 10 May be improved.

In addition, since the first insulating film IF1 is disposed to overlap only the first conductive layer CL1 and the second conductive layer CL2, a volume of the first insulating film IF1 may be reduced. Specifically, the first insulating film IF1 according to the disclosure may have a smaller volume compared to a case in which the first insulating film IF1 overlaps the second conductive layer CL2 as a whole. Accordingly, defects due to the outgassing generated by the first insulating film IF1 may be minimized. Accordingly, the reliability of the display device 10 May be improved.

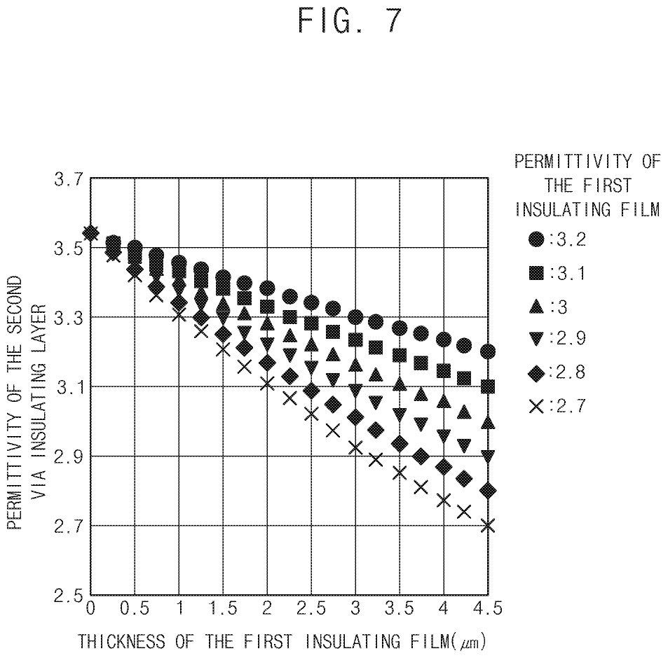

FIG. 7 is a graph illustrating the permittivity of the second via insulating layer VIA2 depending on the thickness of the first insulating film IF1.

Referring to FIGS. 6 and 7, a thickness T2 of the second via insulating layer VIA2 is about 4.5 micrometers, the second via insulating layer VIA2 was formed with the first insulating film IF1 and the second insulating film IF2 completely overlapping each other, and in case that the permittivity of the first insulating film IF1 is in a range of about 2.7 to about 3.2, the permittivity of the second via insulating layer VIA2 depending on the thickness T1 of the first insulating film IF1 was measured.

As shown in the graph of FIG. 7, the permittivity of the second via insulating layer VIA2 may vary depending on the thickness T1 of the first insulating film IF1. For example, the second via insulating layer VIA2 may include the first insulating film IF1 and the second insulating film IF2, the first insulating film IF1 may have the smaller permittivity than that of the second insulating film IF2, and as the thickness T1 of the first insulating film IF1 increases, the permittivity of the second via insulating layer VIA2 may decrease.

In case that the thickness T1 of the first insulating film IF1 is about 0, the second via insulating layer VIA2 may include only the second insulating film IF2. Accordingly, the permittivity of the second insulating film IF2 and the permittivity of the second via insulating layer VIA2 are substantially the same may be confirmed.

In addition, as the permittivity of the first insulating film decreases, a change of the permittivity of the second via insulating layer VIA2 depending on the thickness T1 of the first insulating film IF1 is increased may be confirmed.

In an embodiment, as the thickness T1 of the first insulating film IF1 increases, a ratio occupied by the first insulating film IF1 in the second via insulating layer VIA2 may increase. Therefore, as the ratio occupied by the first insulating film IF1 having smaller permittivity increases, the permittivity of the second via insulating layer VIA2 may decrease.

In an embodiment, as the thickness T1 of the first insulating film IF1 in the display device increases or the permittivity of the first insulating film IF1 decreases and the permittivity of the second via insulating layer VIA2 may decrease. As the permittivity of the second via insulating layer VIA2 disposed between the first conductive layer CL1 and the second conductive layer CL2, the parasitic capacitance between the first conductive layer CL1 and the second conductive layer CL2 may decrease. As the parasitic capacitance decreases, the stains of the display device may be prevented and the display quality may be improved.

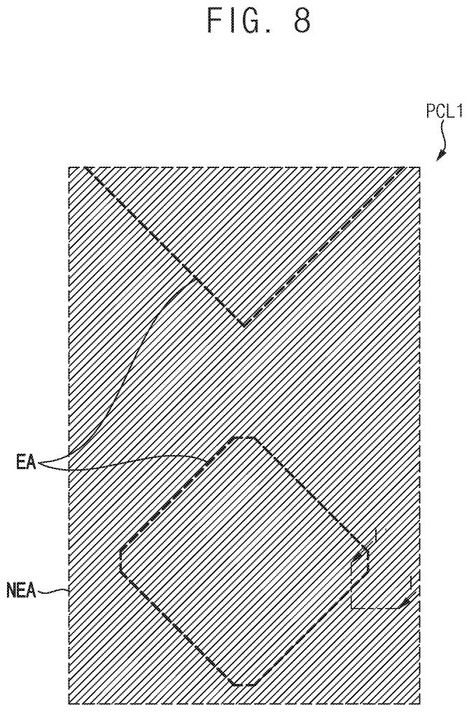

FIGS. 8 to 21 are schematic views illustrating a method of manufacturing a display device according to an embodiment of the disclosure.

For example, the method of manufacturing the display device described with reference to FIGS. 8 to 21 May be the method of manufacturing the display device 10 described with reference to FIGS. 1 to 7. In addition, hereinafter, from a step of forming the first conductive layer CL1 on the first via insulating layer VIA1 among the method of manufacturing the display device will be described.

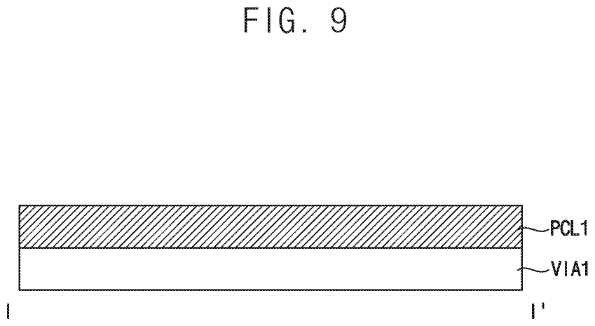

FIG. 9 is a schematic cross-sectional view taken along line I-I′ of FIG. 8.

Referring to FIGS. 8 and 9, a first preliminary conductive layer PCL1 may be formed on the substrate (e.g., the substrate SUB of FIG. 6). Specifically, the first preliminary conductive layer PCL1 may be formed on the first via insulating layer VIA1. The first preliminary conductive layer PCL1 may be formed on the light emitting area EA and the non-light emitting area NEA.

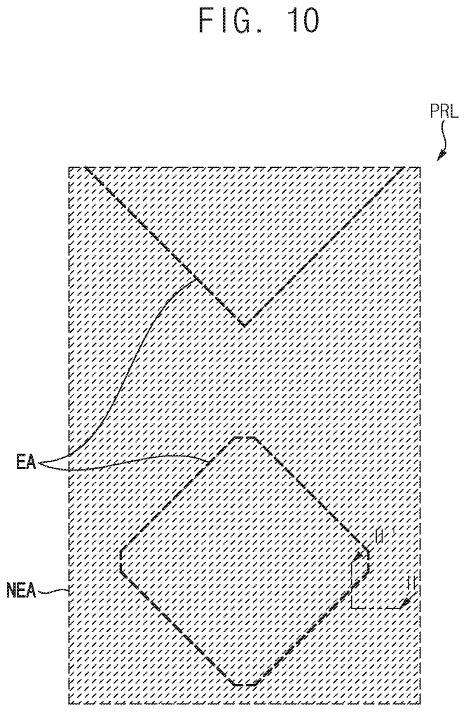

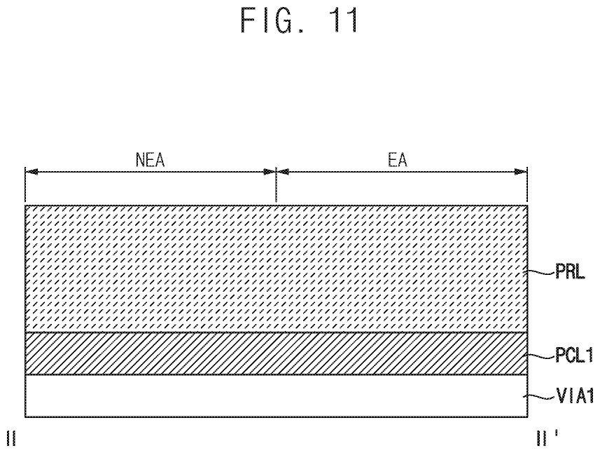

FIG. 11 is a schematic cross-sectional view taken along line II-II′ of FIG. 10.

Further referring to FIGS. 10 and 11, a photoresist layer PRL may be formed on the first preliminary conductive layer PCL1. The photoresist layer PRL may overlap the first preliminary conductive layer PCL1. For example, the photoresist layer PRL may overlap the first preliminary conductive layer PCL1 as a whole. The photoresist layer PRL may be formed of acrylate, siloxane hybrid, and the like.

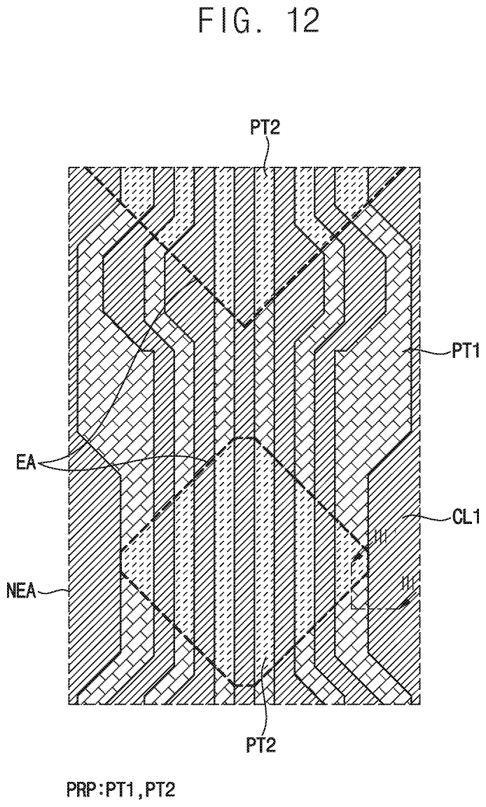

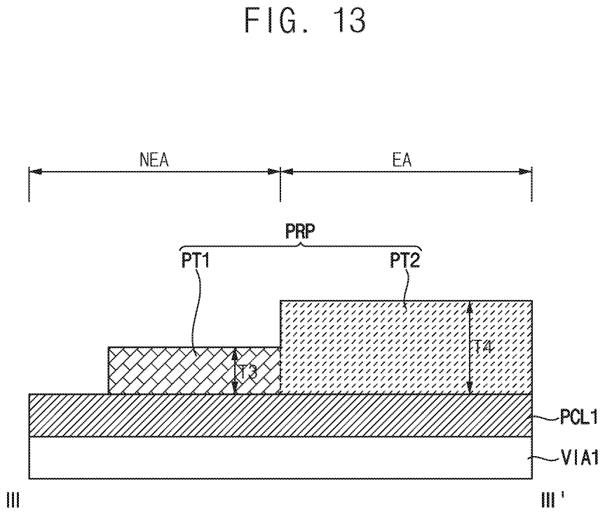

FIG. 13 is a schematic cross-sectional view taken along line III-III′ of FIG. 12

Further referring to FIGS. 12 and 13, in an embodiment, the photoresist layer PRL may be patterned. For example, the photoresist layer PRL may be patterned by using a half-tone mask. Accordingly, the photoresist layer PRL may be patterned to form a photoresist pattern PRP including a first portion PT1 and a second portion PT2 having different thicknesses.

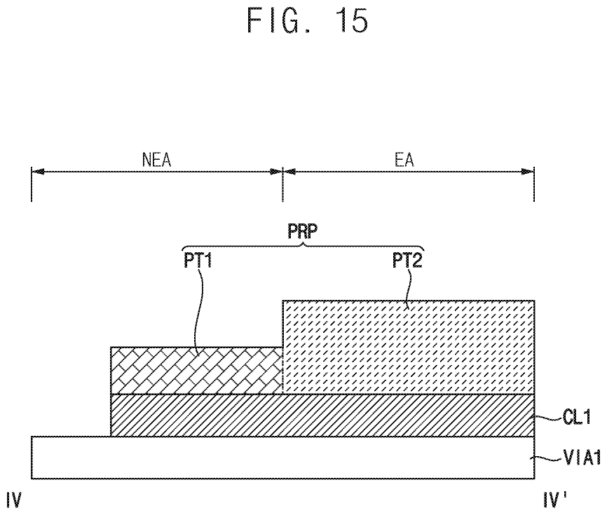

In an embodiment, a thickness T3 of the first portion PT1 may be smaller than a thickness T4 of the second portion PT2. The first portion PT1 may be disposed in the non-light emitting area NEA. The second portion PT2 may be disposed in the light emitting area EA. The first portion PT1 may be formed to have substantially a same shape as the first conductive layer (e.g., the first conductive layer CL1 of FIG. 15) to be formed later in the non-light emitting area NEA. The second portion PT2 may be formed to have substantially a same shape as the first conductive layer to be formed later in the light emitting area EA. For example, the first portion PT1 may overlap the first conductive layer in the non-light emitting area NEA. The second portion PT2 may overlap the first conductive layer in the light emitting area EA. However, the disclosure is not limited thereto, and the photoresist pattern PRP may be larger or smaller than the first conductive layer.

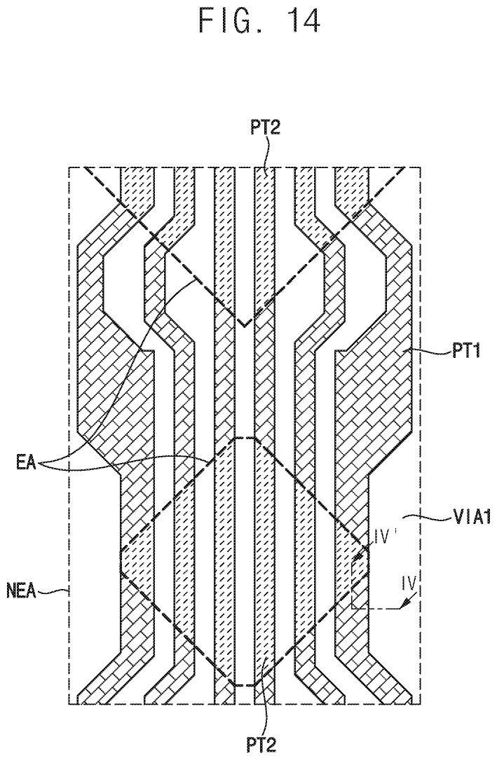

FIG. 15 is a schematic cross-sectional view taken along line IV-IV′ of FIG. 14.

Further referring to FIGS. 14 and 15, the first preliminary conductive layer PCL1 may be patterned with the photoresist pattern PRP. Accordingly, the first conductive layer CL1 overlapping the photoresist pattern PRP may be formed.

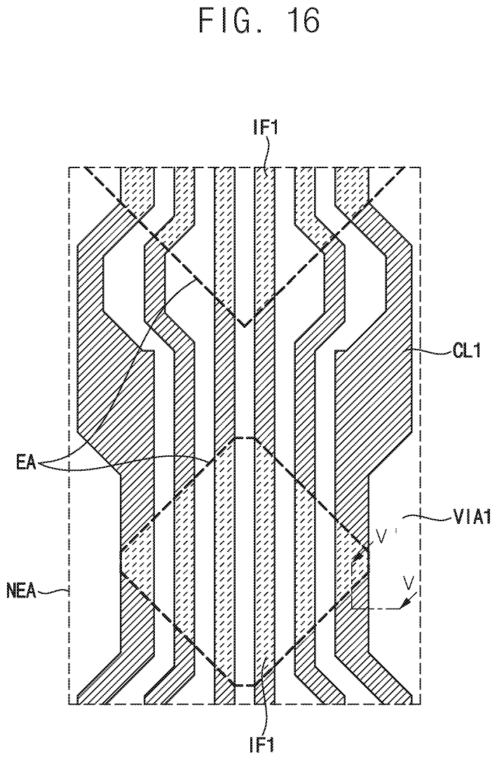

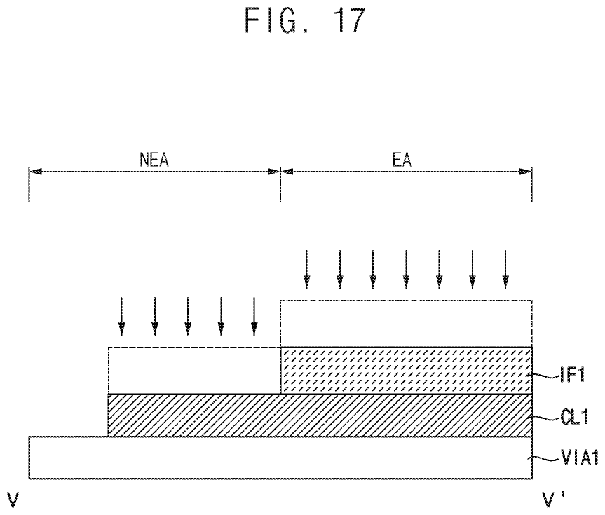

FIG. 17 is a schematic cross-sectional view taken along line V-V′ of FIG. 16.

Further referring to FIGS. 16 and 17, ashing may be performed on the photoresist pattern PRP. In the ashing of the photoresist pattern PRP, the first portion PT1 and the second portion PT2 may be removed by a uniform thickness.

Specifically, the first portion PT1 and the second portion PT2 of the photoresist pattern PRP may be removed by the uniform thickness, and thus the first portion PT1 may be removed entirely and the thickness of the second portion PT2 may be reduced. Accordingly, the first insulating film IF1 only in the light emitting area EA may be formed. For example, the first insulating film IF1 may be a layer formed by thinning the thickness of the second portion PT2 of the photoresist pattern PRP. For example, the first insulating film may be formed by removing the first portion PT1 and the second portion PT2 of the photoresist pattern PRP to by the uniform thickness to remove an entirety of the first portion PT1 and a portion of the second portion PT2.

In an embodiment, the first insulating film IF1 may be formed on the first conductive layer CL1 in the light emitting area EA and may overlap the first conductive layer CL1. The first insulating film IF1 may be formed in substantially the same shape as the first conductive layer CL1 in the light emitting area EA. In addition, the first insulating film IF1 may have the first permittivity.

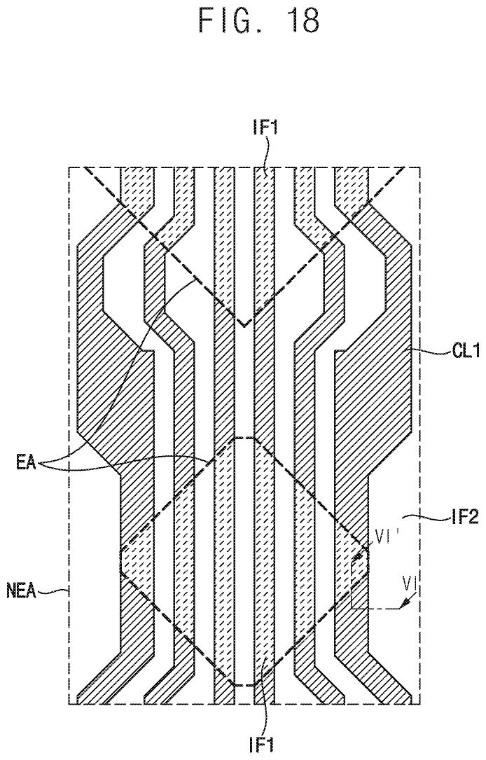

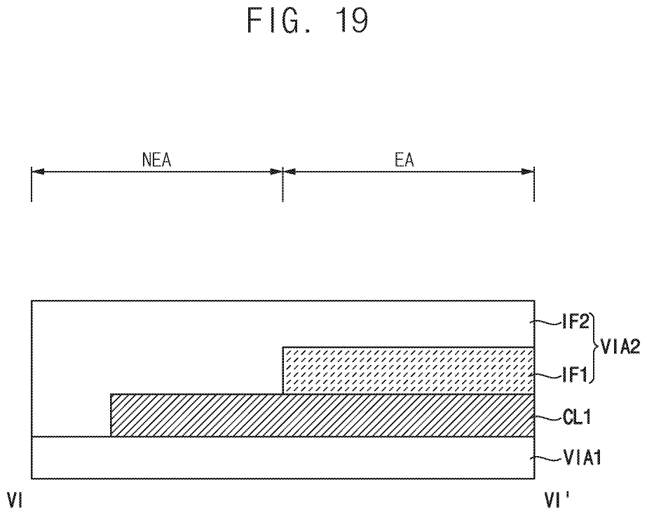

FIG. 19 is a schematic cross-sectional view taken along line VI-VI′ of FIG. 18.

Further referring to FIGS. 18 and 19, the second insulating film IF2 may be formed on the first insulating film IF1 and the first conductive layer CL1. The second insulating film IF2 may cover the first insulating film IF1 and the first conductive layer CL1. The first insulating film IF1 and the second insulating film IF2 may form the second via insulating layer VIA2.

In an embodiment, the first insulating film IF1 and the second insulating film IF2 may be formed of different materials each other. For example, the second insulating film IF2 may be formed of the photo-sensitive polyimide based resin. The second insulating film IF2 may have the second permittivity. The second permittivity may be greater than the first permittivity. Accordingly, the permittivity of the second via insulating layer VIA2 may be reduced due to the first insulating film IF1.

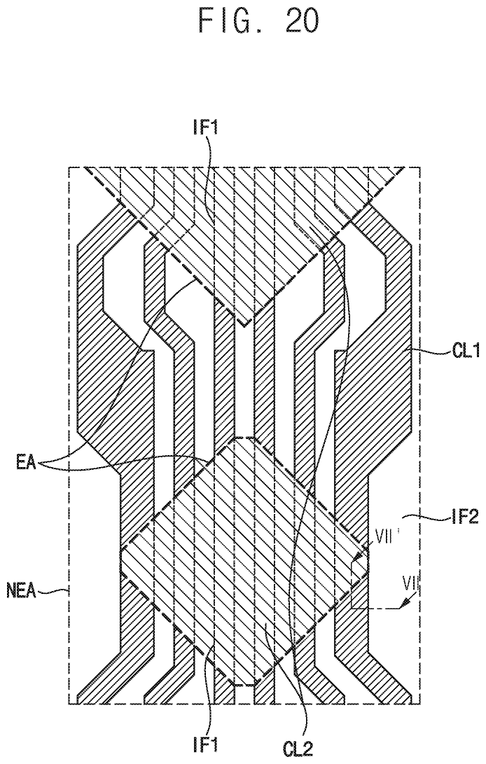

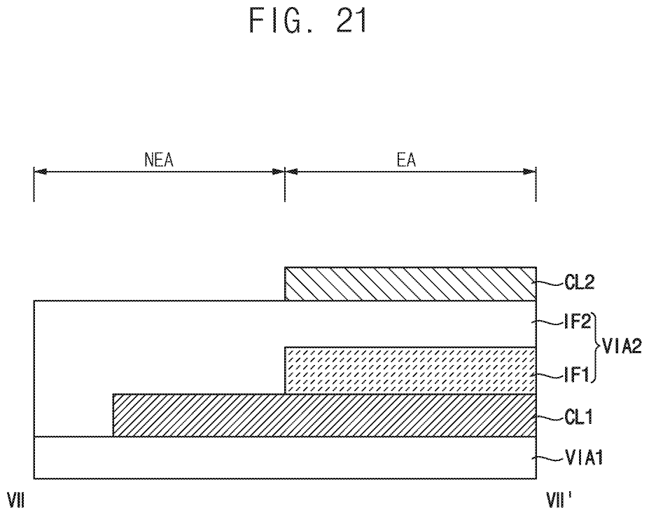

FIG. 21 is a schematic cross-sectional view taken along line VII-VII' of FIG. 20.

Further referring to FIGS. 20 and 21, the second conductive layer CL2 may be formed on the second insulating film IF2. The second conductive layer CL2 may be disposed in the light emitting area EA. The second conductive layer CL2 may partially overlap the first insulating film IF1 in the light emitting area EA.

In an embodiment, by forming the first insulating film IF1 using the half-tone mask and the ashing process, an additional process for forming the first insulating film IF1 may be omitted. Therefore, while reducing the permittivity of the second via insulating layer VIA2 with the first insulating film IF1, and the efficiency of manufacturing process might not decrease.

The disclosure may be applied to, e.g., a display device included in a computer, a laptop, a mobile phone, a smart phone, a smart pad, an automobile, a PMP, a PDA, a MPE, or the like.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting area and a non-light emitting area adjacent to the light emitting area;
a first conductive layer disposed on a substrate in the light emitting area and the non-light emitting area;
a second conductive layer disposed on the first conductive layer and disposed in the light emitting area;
a first insulating film disposed on the first conductive layer, overlapping the first conductive layer and the second conductive layer in the light emitting area, and having a first permittivity; and
a second insulating film disposed between the first insulating film and the second conductive layer, disposed in the light emitting area and the non-light emitting area, overlapping the first insulating film and the first conductive layer, and having a second permittivity greater than the first permittivity.

2. The display device of claim 1, wherein the first insulating film and the second insulating film include different materials.

3. The display device of claim 1, wherein the first insulating film includes at least one selected from a group consisting of acrylate and siloxane hybrid.

4. The display device of claim 1, wherein the second insulating film includes a photo-sensitive polyimide-based resin.

5. The display device of claim 1, wherein the first insulating film has a same shape as the first conductive layer in the light emitting area.

6. The display device of claim 1, wherein,
the first conductive layer defines at least one first opening disposed in the light emitting area, and
the first insulating film defines at least one second opening disposed in the light emitting area.

7. The display device of claim 6, wherein the first opening and the second opening overlap each other.

8. The display device of claim 1, further comprising:
a light emitting diode disposed on the first conductive layer and disposed in the light emitting area.

9. The display device of claim 8, wherein the light emitting diode includes:
the second conductive layer;
a light emitting layer disposed on the second conductive layer; and
a common electrode disposed on the light emitting layer.

10. The display device of claim 8, further comprising:
a transistor disposed on the substrate and disposed under the first conductive layer.

11. The display device of claim 10, wherein the transistor includes:
an active layer disposed on the substrate;
a gate electrode disposed on the active layer; and
a source electrode and a drain electrode connected to the active layer on the gate electrode.

12. The display device of claim 10, wherein the transistor is electrically connected to the light emitting diode through the first conductive layer.

13. The display device of claim 1, wherein the first conductive layer further includes a data line.

14. The display device of claim 1, wherein each of the first conductive layer and the second conductive layer includes a metal material.

15. The display device of claim 14, wherein the second conductive layer includes at least one selected from a group consisting of indium tin oxide (ITO), indium zinc oxide (IZO), zinc oxide (ZnO), indium oxide (In₂O₃), indium gallium oxide (IGO), and aluminum zinc oxide (AZO).

16. A method of manufacturing a display device comprising:
forming a first conductive layer on a substrate;
forming a first insulating film on the first conductive layer, overlapping the first conductive layer in a light emitting area of the display device, and having a first permittivity;
forming a second insulating film on the first insulating film, overlapping the first insulating film and the first conductive layer, and having a second permittivity greater than the first permittivity; and
forming a second conductive layer on the second insulating film and overlapping the first insulating film in the light emitting area.

17. The method of claim 16, wherein the forming of the first conductive layer and the first insulating film includes:
forming a first preliminary conductive layer on the substrate;
forming a photoresist layer on the first preliminary conductive layer;
forming a photoresist pattern including a first portion and a second portion having different thicknesses by patterning the photoresist layer;
forming a first conductive layer by patterning the first preliminary conductive layer with the photoresist pattern; and
forming the first insulating film by ashing the photoresist pattern.

18. The method of claim 17, wherein a thickness of the first portion is smaller than a thickness of the second portion.

19. The method of claim 18, wherein the photoresist pattern is patterned by using a half-tone mask.

20. The method of claim 17, wherein in the ashing of the photoresist pattern, the first portion and the second portion are removed by a uniform thickness.

21. The method of claim 20, wherein the first insulating film is formed by removing the first portion and the second portion of the photoresist pattern by the uniform thickness to remove an entirety of the first portion and a portion of the second portion.

22. The method of claim 17, wherein, the first portion overlaps the first conductive layer in a non-light emitting area of the display device, and the second portion overlaps the first conductive layer in the light emitting area.

23. The display device of claim 17 wherein the photoresist layer includes at least one selected from a group consisting of acrylate and siloxane hybrid.
